(19) United States
(12) Patent Application Publication
(10) Pub. No.: US 2007/0231712 A1
(43) Pub. Date: Oct. 4, 2007

(54) Alternating phase shift masking

(76) Inventors: Song Pang, Berkeley, CA (US); Jeff Farnsworth, Los Gatos, CA (US); Kishore K. Chakravorty, San Jose, CA (US); Karmen Yung, Sunnyvale, CA (US); Joas L. Chavez, Newark, CA (US)

Correspondence Address: TROP PRUNER & HU, PC, 1616 S. VOSS ROAD, SUITE 750, HOUSTON, TX, 77057-2631, US

(21) Appl. No.: 11/394,014

(22) Filed: Mar. 30, 2006

(51) Int. Cl. G03C 5/00; G03F 1/00

(52) U.S. Cl. 430/5; 430/323; 430/324

(57) ABSTRACT

An alternating phase shift mask may be formed using a dry undercut etch. The dry undercut etch reduces problems associated with wet etching of quartz or glass masks. In addition, the use of the dry undercut etch enables image balancing between the zero and pi apertures. This approach is not limited by specific optical proximity corrected design patterns or chromium layer thickness.

### BACKGROUND

This invention relates generally to lithography and, particularly, to lithography that aims to recreate features on a semiconductor substrate having feature sizes less than the lithographic system wavelength.

In lithography, a mask may be formed which has a pattern. That pattern may then be transferred to a semiconductor substrate covered with photoresist. The pattern, once transferred to the photoresist, is called an aerial image.

The mask may be a structure which has regions of different phase and/or intensity transmittance. For example, the mask may be formed of quartz or glass having a pattern of chromium regions formed thereon. The chromium regions do not pass radiation, whereas the quartz or glass regions do.

Thus, by providing an appropriately patterned chromium layer on a glass or quartz substrate, a mask can be formed and then exposed to radiation. The radiation may transmit through the mask to expose an underlying wafer covered with photoresist. The photoresist then may be selectively developed to either create a positive or negative image of the pattern on the mask. That image may then be used as a mask itself to etch correspondingly shaped features into the semiconductor structure.

The economies of the semiconductor industry dictate that integrated circuits of progressively smaller size be manufactured. One limit on the size at which devices can be manufactured is the accuracy of the lithographic system that transfers the pattern from the mask to the semiconductor wafer. In order to get progressively smaller resolution, it may be desirable to print features at dimensions below the wavelength of the radiation being utilized to illuminate the mask.

One problem with sub-wavelength lithography is that as the features that are being printed get smaller and closer to one another, diffraction may occur. As a result, so-called resolution enhancement techniques may be needed to extend the usable resolution without decreasing wavelength or increasing the numerical aperture of the imaging equipment.

One such resolution enhancement technique is called phase shift masking. It overcomes the diffraction effect described above by forming adjacent mask features so that they transmit radiation out of phase from one another. The two phases that are produced may be called the zero and pi phases to indicate that they are 180° out of phase.

In some embodiments, the phase shift may be achieved by forming apertures within the mask and, particularly, within the quartz or glass layer of the mask that are of different depths. As a result, the radiation transmitted through the adjacent apertures may be phase shifted so that diffraction effects may be counteracted. In alternating phase shift masking, every other feature is formed by an aperture in the mask which is of different depth so as to be out of phase with the preceding and succeeding features.

### BRIEF DESCRIPTION OF THE DRAWINGS

FIG. 1 is an enlarged, cross-sectional view of a mask being manufactured in accordance with one embodiment of the present invention;

FIG. 2 is an enlarged, cross-sectional view of the mask shown in FIG. 1 at a subsequent stage of manufacture in accordance with one embodiment of the present invention;

FIG. 3 is an enlarged, cross-sectional view of the mask shown in FIG. 2 at a subsequent stage of manufacture in accordance with one embodiment of the present invention;

FIG. 4 is an enlarged, cross-sectional view of the mask shown in FIG. 3 at a subsequent stage of manufacture in accordance with one embodiment of the present invention;

FIG. 5 is an enlarged, cross-sectional view of the mask shown in FIG. 4 at a subsequent stage of manufacture in accordance with one embodiment of the present invention;

FIG. 6 is an enlarged, cross-sectional view of the mask shown in FIG. 5 at a subsequent stage of manufacture in accordance with one embodiment of the present invention;

FIG. 7 is an enlarged, cross-sectional view of the mask shown in FIG. 6 upon completion in accordance with one embodiment of the present invention;

FIG. 8 is a depiction of a process for forming a mask in accordance with some embodiments of the present invention, the flow chart indicating exemplary Bossung curves to illustrate the indicated steps; and

FIG. 9A is a depiction of a dry undercut cross-section in accordance with one embodiment of the present invention; and

FIG. 9B is a depiction of a wet undercut cross-section.

### DETAILED DESCRIPTION

In some embodiments of the present invention, an alternating phase shift mask may be formed using a single, dry undercut etch to achieve etch depth and undercut simultaneously. In some embodiments, replacing wet etching with dry etching may reduce the cracks which may occur with wet etching. These cracks may occur in the glass or quartz layer and are sometimes called microcracks. Other defects from wet etching including enlarged critical dimension defects or pit defects may also be reduced. These defects may be non-reparable and may be disproportionately enlarged by the isotropic wet etch process, leading to mask rejection, even after an extended fabrication process.

In some embodiments, the effective phase may be reduced, and a repair process window may be achieved over conventional processes. By modulating a phase and undercut simultaneously, optical performance can be achieved without OPC resizing, thus, significantly reducing the optical proximity correction (OPC) learning cycle in some embodiments.

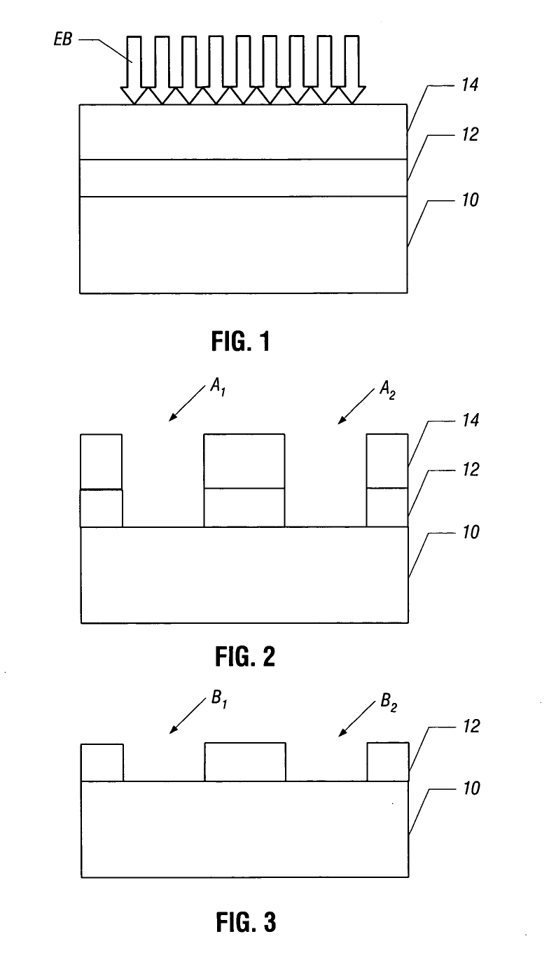

Referring to FIG. 1, a mask may be formed of a radiation transmitting layer 10 formed, for example, of quartz or glass. The layer 10 may be coated with a non-transmissive material 12 including a metal such as chromium. Thereafter a resist 14 may be formed over the material 12. The resist 14 may be exposed to radiation, such as an electron beam (EB), to transfer a pattern to the material 12.

Referring to FIG. 2, after development and etching of the material 12 using the pattern transferred by the electron beam in FIG. 1, a pattern may be formed in the material 12 as indicated in FIG. 2. That pattern may include adjacent apertures A₁ and A₂, one of which will become the pi aperture and the other of which will become the zero aperture.

Of course, the mask may have a large number of such apertures and, in an alternating phase shift mask embodiment, alternating or successive apertures are 180° out of phase. However, only two apertures A₁ and A₂ are shown here, for ease of illustration.

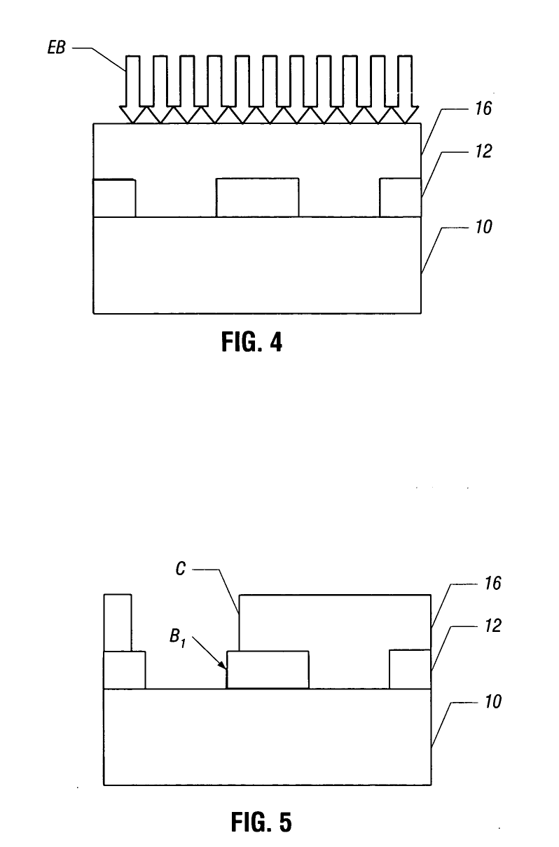

Referring next to FIG. 3, the resist 14 may be stripped, resulting in the apertures B₁ and B₂. Then, as shown in FIG. 4, a second level resist 16 may be deposited over the structure of FIG. 3. The second level resist 16 may be exposed to radiation such as a laser pattern generator or another electron beam as indicated.

Again, as indicated in FIG. 5, the second level resist 16 may be developed. The developed material may be removed to create an opening C in the second level resist 16. As illustrated, the opening C is aligned with the underlying aperture B₁ in the material 12. However, the opening C may actually be wider than the aligned aperture B₁.

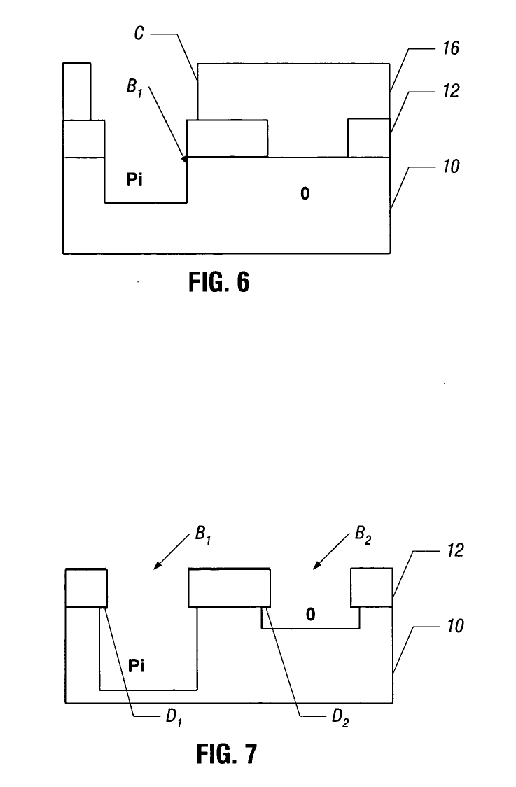

Then, referring to FIG. 6, the layer 10 may be etched to a desired depth in the aperture B₁ to form the pi aperture as indicated. This may be a dry etch in some embodiments of the present invention.

After the phase etching, shown in FIG. 6, the second level resist 16 may be stripped. The pi etch may be a dry etch using a single or multiple fluorine-containing gas recipe to anisotropically etch the layer 10, that may be silicon dioxide. A pure fluorine chemistry may be used or a mixture with nitrogen or oxygen gases. 100 to 1000 Watt power levels may be utilized to ignite and sustain the plasma. A 20 to 300 Watt bias power may be used to obtain ion bombardment energy. The pressure range may be from 4 to 80 milliTorr to ignite and sustain the plasma. An inductively coupled plasma source may be used to etch the silicon dioxide in some embodiments. Other etch conditions may also be used.

Next, as shown in FIG. 7, the pi aperture B₁ and the zero aperture B₂ may be isotropically dry etched to achieve etch depth and undercut (D₁, D₂) simultaneously. The zero and pi aperture depths can be less than 90 nanometers, for example, as shallow as 70 nanometers, and less than 270 nanometers, for example, as shallow as 225 nanometers, respectively, in some embodiments.

The etch shown in FIG. 7 may include a dry undercut etch which is an isotropic etch. It may use a single or multiple fluorine-containing gas recipe to isotropically etch silicon dioxide. Again, it may include a pure fluorine chemistry or a mixture with nitrogen or oxygen, to mention a few examples. The source power may be 300 to 2000 Watts to ignite and sustain higher plasma densities with zero to 300 Watts bias power to minimize bombardment energy. The pressure range may be 4 to 80 milliTorr to ignite and sustain the plasma. An inductively coupled plasma source may be used to etch the silicon dioxide. Other etch conditions may also be used.

In accordance with some embodiments of the present invention, the aim of the steps shown in FIG. 7 is to achieve “image balance.” The phase shift mask image is balanced when the radiation intensity through focus behaves in the same way for both the zero and the pi apertures.

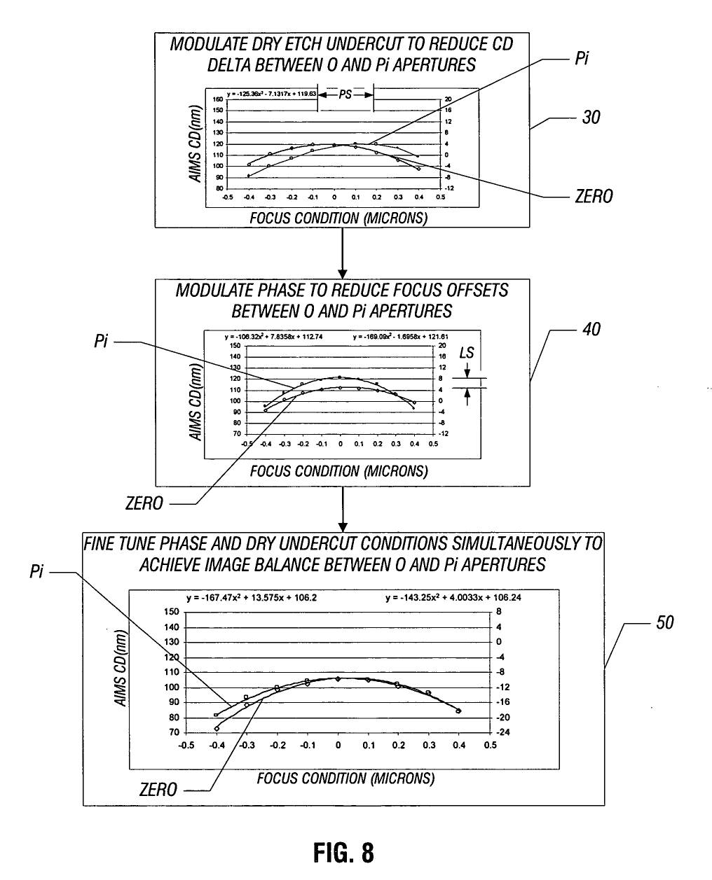

A technique for achieving image balance is illustrated in FIG. 8 in accordance with one embodiment of the present invention. Initially, the dry etch undercut is modulated to reduce the delta between the zero and pi apertures in terms of their undercut critical dimension D₁, D₂. Thus, the first phase of the dry undercut etch, shown in FIG. 7, is to achieve the situation where the Bossung curves appear generally as indicated at block 30 in FIG. 8.

Those skilled in the art will appreciate that the Bossung curve or focus exposure matrix shows the variation in linewidth as a function of both focus and exposure energy plotted as a linewidth versus focus for different exposure energies. The focus is the position of the plane of best focus relative to a reference plane, namely, the top surface of the photoresist, measured along the optical axis.

Thus, referring to FIG. 8 at block 30, the Bossung curve plots the critical dimension in nanometers, namely, the undercut under the material 12, versus the focus condition in microns. The critical dimension is measured in an aerial image measurement system (AIMS).

The dry etch is modulated to reduce the undercut critical dimension (D₁, D₂) delta between the zero and pi apertures. This means that the two Bossung curves for the pi and zero apertures have essentially the same peak critical dimension, even though they may be offset in terms of focus. That offset or phase separation is indicated as PS in FIG. 8 at block 30. It indicates the distance between the two peaks of the pi and zero aperture plots.

Basically, what is done in FIG. 8, at block 30, is to modulate the intensity in the y direction. Thus, the undercut amount is effectively equalized by etching the pi and the zero apertures at the same time and making the undercuts substantially the same. The initial difference in depths of the pi and zero apertures makes it more difficult to get the undercut substantially the same. However, the longer that the pi aperture is etched, the larger is the undercut. Thus, by etching long enough, the condition shown in FIG. 8 at block 30 may be achieved.

As a result of modulating the dry etch undercut to reduce the critical dimension delta, a phase difference is created. The phase difference is the result of the incorrect relative depths of the pi and zero apertures. Recall that those relative depths are what are intended to create the 180° phase shift.

Thus, at block 40, the phase is modulated to reduce the focus offset between the zero and pi apertures. Note that as a result of this correction, the Bossung curves for the zero and pi apertures are now aligned in terms of focus, but are again offset in terms of critical dimension. That offset is indicated as a line separation LS delta at block 40 in FIG. 8. This means that there is still a light intensity separation between the two Bossung curves for the pi and zero apertures.

In the next block, block 50, shown in FIG. 8, the phase and undercut are fine tuned simultaneously to achieve image balance between the zero and pi apertures. As can be seen in FIG. 8, the zero and pi apertures substantially overlap, being substantially similar in both focus and critical dimensions. There is little separation in either the x or y directions. In some embodiments, the sequence indicated by blocks 30, 40, and 50 may be repeated.

In one embodiment of the present invention, the etch step, indicated in block 30, may be a 1740 phase etch, in the form of a 1x dry undercut etch. The etch used in block 40 may be a 1650 phase etch, in the form of a 1x undercut etch in one embodiment. Finally, the etch used in block 50 may be a 1660 phase etch, using an 0.96x dry undercut etch in one embodiment. These etch targets (phase target and corrected undercut target) may be different for different optical proximity corrected designed patterns.

In some embodiments of the present invention, different OPC design solutions may be flexibly achieved, including eliminating the crack defects decorated by wet etches, while reducing the effective phase, gaining repair process window over conventional processes. In some embodiments, a tunable image balance solution may be provided with the flexibility of modulating the phase and undercut simultaneously to achieve the same optical performance for any existing OPC design without OPC resizing in some embodiments. This may significantly reduce the OPC learning curve. In addition, in some cases, the non-repairable quartz cracks and pit type of printable defects may be reduced or eliminated. Moreover, the decoration or enlargement of microcrack defects in the quartz may be significantly reduced, while providing the same image balance quality in some cases.

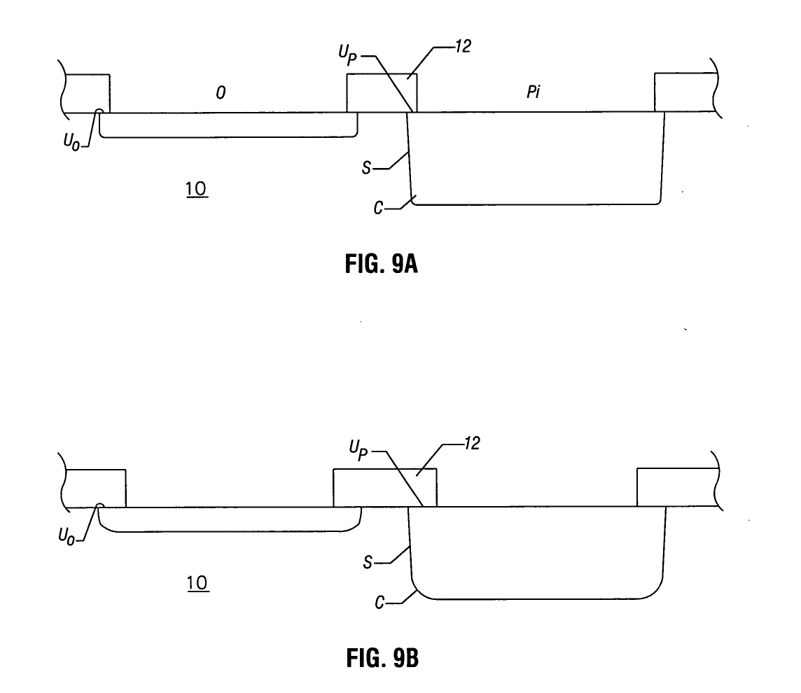

Referring to FIG. 9A, as a result of the dry etch, a characteristic dry undercut cross-section is formed. It is characterized by having less sidewall slope S and less corner rounding C than with wet undercut etch (FIG. 9B).

The undercut amount U is highly dependent on the image balance condition for a given optical proximity corrected design. Less undercut U under the non-transmissive material 12 is obtained in some cases. Less undercut U₀ may be observed on the zero aperture than on the pi aperture in some cases.

The characteristic dry undercut cross-section may be better appreciated by comparing a corresponding wet undercut cross-section shown in FIG. 9B. Note the greater sidewall slope S and more severe corner rounding C.

In some cases, more undercut under the non-transmissive material 12, as indicated at U, is observed.

Thus, one skilled in the art will appreciate that FIG. 9A is a characteristic dry undercut cross-section and FIG. 9B is a characteristic wet undercut cross-section, each being distinguishable at least in corner rounding and sidewall slope.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming an alternating phase shift mask using a dry undercut etch.

2. The method of claim 1 including using a dry undercut etch to initially reduce the delta between the undercut on zero and pi apertures.

3. The method of claim 2 including modulating the phase to reduce the focus offset between the zero and pi apertures.

4. The method of claim 3 including tuning the phase and dry undercut etching conditions to simultaneously achieve both undercut dimension and focus condition balance between the zero and pi apertures.

5. The method of claim 1 including forming an image balance condition with a zero aperture depth of less than 90 nanometers and a pi aperture depth of less than 270 nanometers.

6. The method of claim 1 including performing an isotropic dry etch followed by an anisotropic dry etch.

7. A lithography mask comprising:
a first material; and
a second material under said first material, said second material being more radiation transmissive than said first material, said second material having alternating phase shift trenches, said trenches having a characteristic dry undercut cross-sectional profile.

8. The mask of claim 7 wherein said trenches define zero and pi apertures.

9. The mask of claim 8 including a zero aperture depth of less than 90 nanometers and a pi aperture depth of less than 270 nanometers.

10. The mask of claim 7 wherein said second material is non-transmissive.

11. The mask of claim 10 wherein said second material includes chromium.

12. The mask of claim 7 wherein the trenches have less sidewall slope and corner rounding than in the case of a wet undercut.

13. A method comprising:
modulating a dry etch undercut of zero and pi apertures in a phase shift mask to reduce the critical dimension delta between the apertures;
modulating the phase to reduce the focus offsets between the zero and pi apertures; and
tuning the phase and dry undercut etch conditions simultaneously to achieve image balance between the zero and pi apertures.

14. The method of claim 13 including forming an alternating phase shift mask with a zero aperture depth of less than 90 nanometers and a pi aperture depth of less than 270 nanometers.

15. The method of claim 13 including simultaneously etching the pi and zero apertures using a plasma etch.

16. The method of claim 13 including isotropically etching using a dry etch.

17. The method of claim 13 including anisotropically etching using a dry etch.

18. The method of claim 13 including using alternating isotropic and anisotropic dry etches.
